(19) United States
(12) Patent Application Publication
(10) Pub. No.: US 2012/0068187 A1
(43) Pub. Date: Mar. 22, 2012

(54) SOLID STATE LIGHTING DEVICES WITH IMPROVED COLOR UNIFORMITY AND METHODS OF MANUFACTURING

(75) Inventors: Vladimir Odnoblyudov, Eagle, ID (US); Kevin Tetz, Boise, ID (US); Martin F. Schubert, Boise, ID (US)

(73) Assignee: MICRON TECHNOLOGY, INC., Boise, ID (US)

(21) Appl. No.: 12/885,703

(22) Filed: Sep. 20, 2010

(51) Int. Cl. H01L 33/30; H01L 21/66; H01L 33/50

(52) U.S. Cl. 257/76; 257/98; 438/15; 257/E33.034; 257/E33.055; 257/E21.529

(57) ABSTRACT

Solid state lighting (SSL) devices with good color uniformity and methods of manufacturing are disclosed herein. In one embodiment, an SSL device includes a support structure, an SSL die in the support structure, and a converter material at least partially encapsulating the SSL die. The converter material is configured to emit under excitation. The converter material has a surface facing away from the SSL die, and the surface of the converter material has a generally convex shape.

### TECHNICAL FIELD

The present disclosure is related to solid state lighting (SSL) devices (e.g., devices with light emitting diodes (LEDs)) with good color uniformity and methods of manufacturing.

### BACKGROUND

Mobile phones, personal digital assistants (PDAs), digital cameras, MP3 players, and other portable electronic devices utilize SSL devices for background illumination. SSL devices are also used for signage and for indoor, outdoor, and general illumination. However, LEDs typically only emit at one particular wavelength. For human eyes to perceive the color white, a mixture of wavelengths is needed.

One conventional technique for producing white light with SSLs includes depositing a converter material (e.g., a phosphor) on a light emitting structure. For example, as shown in FIG. 1A, a conventional SSL device 10 includes a support 2 carrying an LED die 4 and a converter material 6 substantially encapsulating the LED die 4. In another example, as shown in FIG. 1B, another conventional SSL device 11 has the converter material 6 formed only on an upper surface 4a of the LED die 4.

Referring to both FIGS. 1A and 1B, in operation, the LED die 4 can produce LED emissions (e.g., a blue light) at different angles in response to an applied electrical voltage. For example, the LED die 4 can produce a first emission 8a that is substantially perpendicular to the upper surface 4a, and a second emission 8b that is at an angle α other than 90° with respect to the upper surface 4a. The LED emissions 8a and 8b can stimulate the converter material 6 to produce converted emissions (e.g., a yellow light). The combination of the blue and yellow lights appears white to human eyes if matched appropriately.

One operational difficulty of the SSL devices 10 and 11 is color non-uniformity for emissions at different angles (e.g., the first and second emissions 8a and 8b). FIG. 1C is an example of a color coordinate change versus angle plot for the SSL devices 10 and 11. As shown in FIG. 1C, the chromaticity coordinate is shifted by a distance of about 0.016 and about 0.020 between 0° and 60° angles for the SSL device 10 and for the SSL device 11, respectively. The large color variations can diminish product consistency, detract from user experience, and slow the adoption of SSL-based lighting systems for general illumination applications. Accordingly, several improvements in color uniformity of SSL devices may be desirable.

### BRIEF DESCRIPTION OF THE DRAWINGS

FIG. 1A is a schematic cross-sectional diagram of an SSL device in accordance with the prior art.

FIG. 1B is a schematic cross-sectional diagram of another SSL device in accordance with the prior art.

FIG. 1C is an example of color coordinate change versus angle plot for the SSL devices shown in FIGS. 1A and 1B.

FIGS. 2A-2D are schematic cross-sectional diagrams of an SSL device with improved angular color uniformity in accordance with embodiments of the technology.

FIG. 3 is a flow chart illustrating a method of generating curvature values for the converter material in FIGS. 2A-2D in accordance with embodiments of the technology.

FIGS. 4A-4D are schematic cross-sectional diagrams of an SSL die undergoing a process to form the SSL device in FIGS. 2A-2D in accordance with embodiments of the technology.

FIG. 5 is a schematic cross-sectional diagram of a pre-form stamp useful for forming the converter material in FIGS. 2A-2D in accordance with embodiments of the technology.

FIGS. 6A and 6B are schematic cross-sectional diagrams of an SSL device with a plurality of SSL dies in accordance with embodiments of the technology.

### DETAILED DESCRIPTION

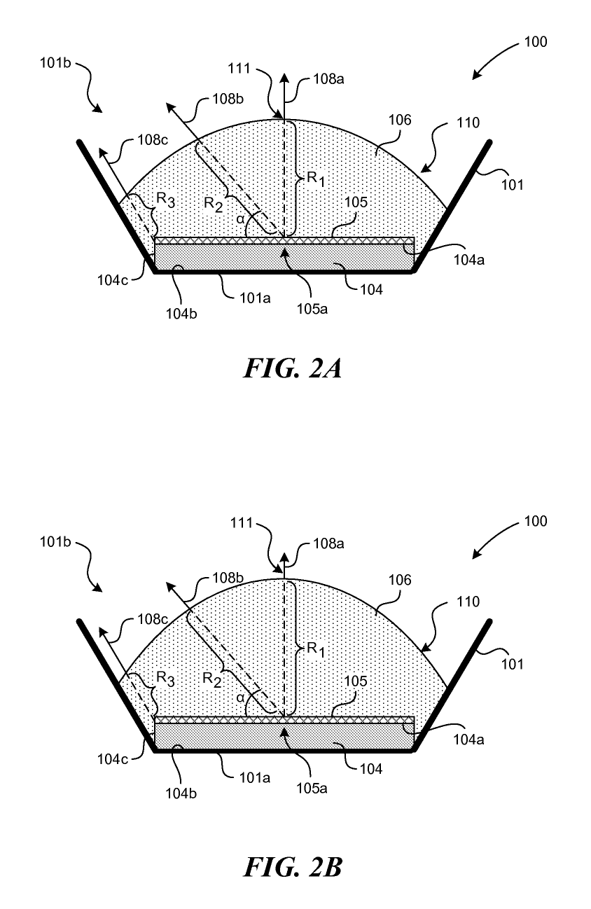

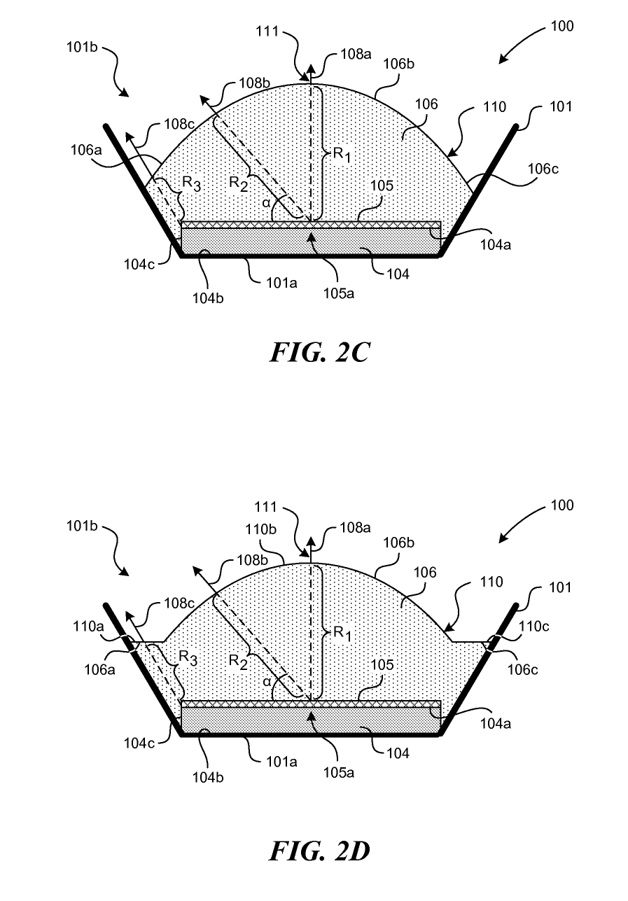

Various embodiments of SSL devices, assemblies, and methods of manufacturing are described below. As used hereinafter, the term “SSL die” generally refers to a solid state emitter, such as an LED die, a laser diode (“LD”) die, a polymer light emitting diode (“PLED”) die, and/or other suitable solid state structures that emit electromagnetic radiation in a desired spectrum other than electrical filaments, a plasma, or a gas. The term “converter material” generally refers to a material that can continue emitting light after exposure to energized particles (e.g., electrons and/or photons). For example, a converter material can emit a lower energy light with absorption of a higher energy light. A person skilled in the relevant art will also understand that the technology may have additional embodiments and that the technology may be practiced without several of the details of the embodiments described below with reference to FIGS. 2A-6B.

FIG. 2A is a schematic cross-sectional diagram of an SSL device 100 in accordance with embodiments of the technology. As shown in FIG. 2A, the SSL device 100 includes a support structure 101 carrying an SSL die 104 and a converter material 106. In the illustrated embodiment, the converter material 106 is substantially contained in the support structure 101 and generally encapsulates the SSL die 104. In other embodiments, the converter material 106 may be partially contained in the support structure 101 and/or may have other suitable configurations. Even though only the foregoing components of the SSL device 100 are shown in FIG. 2A, in other embodiments, the SSL device 100 can also include an encapsulant, lenses, color filters, and/or other suitable peripheral components.

The support structure 101 can include any suitable structures for carrying and/or otherwise holding the SSL die 104 and the converter material 106. For example, in the illustrated embodiment, the support structure 101 has a trapezoidal cross section with a closed end 101a opposite an open end 10 lb. In other embodiments, the support structure 101 may also have a generally rectangular cross section, a truncated conical cross section, and/or other suitable configurations. In certain embodiments, the support structure 101 can be constructed from silicon (Si), gallium nitride (GaN), aluminum nitride (AlN), and/or other suitable semiconductor materials. In other embodiments, the support structure 101 can be constructed from copper (Cu), aluminum (Al), tungsten (W), stainless steel, and/or other suitable metal and/or metal alloys. In further embodiments, the support structure 101 can be constructed from diamond, glass, quartz, silicon carbide (SiC), aluminum oxide (Al₂O₃), and/or other suitable crystalline or ceramic materials.

The SSL die 104 can include a single LED die or a plurality of LED dies arranged in an array. As shown in FIG. 2B, the SSL die 104 can include a first surface 104a facing the open end 101b of the support structure 101 and a second surface 104b in contact with the closed end 101a of the support structure 101. The SSL die 104 can further include side surfaces 104c between the first and second surfaces 104a and 104b. In one embodiment, the SSL die 104 can include an N-type gallium nitride (GaN) material, an indium gallium nitride (InGaN) material, and a P-type GaN material (not shown) on one another in series. In other embodiments, the SSL die 104 can also include gallium arsenide (GaAs), aluminum nitride (AlN), aluminum gallium arsenide (AlGaAs), gallium arsenide phosphide (GaAsP), gallium(III) phosphide (GaP), zinc selenide (ZnSe), boron nitride (BN), aluminum gallium indium phosphide (AlGaInP), aluminum gallium indium nitride (AlGaInN), and/or other suitable materials or configurations.

The SSL die 104 can be configured to emit radiation in the visible spectrum (e.g., from about 400 nm to about 750 nm), in the infrared spectrum (e.g., from about 680 nm to about 970nm), in the near infrared spectrum (e.g., from about 1050 nm to about 1550 nm), and/or in other suitable spectra. In the illustrated embodiment, the SSL die 104 can emit via an emission area 105 at least proximate the first surface 104a and via the side surfaces 104c. In other embodiments, the SSL die 104 can emit only via the emission area 105. In further embodiments, the SSL die 104 can have other suitable structures and/or functions.

The converter material 106 can be configured to emit radiation at a desired wavelength under excitation (e.g., photoluminescence and/or electroluminescence) such that a combination of the emissions from the SSL die 104 and from the converter material 106 can emulate a target color (e.g., white light). For example, in one embodiment, the converter material 106 can include a phosphor containing cerium(III)-doped yttrium aluminum garnet (YAG) at a particular concentration for emitting a range of colors from green to yellow and to red under photoluminescence. In other embodiments, the converter material 106 can include neodymium-doped YAG, neodymium-chromium double-doped YAG, erbium-doped YAG, ytterbium-doped YAG, neodymium-cerium double-doped YAG, holmium-chromium-thulium triple-doped YAG, thulium-doped YAG, chromium(IV)-doped YAG, dysprosium-doped YAG, samarium-doped YAG, terbium-doped YAG, and/or other suitable phosphor compositions. In yet other embodiments, the converter material 106 can include europium phosphors (e.g., CaS:Eu, CaAlSiN₃:Eu, Sr₂Si₅N₈:Eu, SrS:Eu, Ba₂Si₅N₈:Eu, Sr₂SiO₄:Eu, SrSi₂N₂O₂:Eu, SrGa₂S₄:Eu, SrAl₂O₄:Eu, Ba₂SiO₄:Eu, Sr₄Al1₄O₂₅:Eu, SrSiAl₂O₃N:Eu, BaMgAl₁₀O₁₇:Eu, Sr₂P₂O₇:Eu, BaSO₄:Eu, and/or SrB₄O₇:Eu).

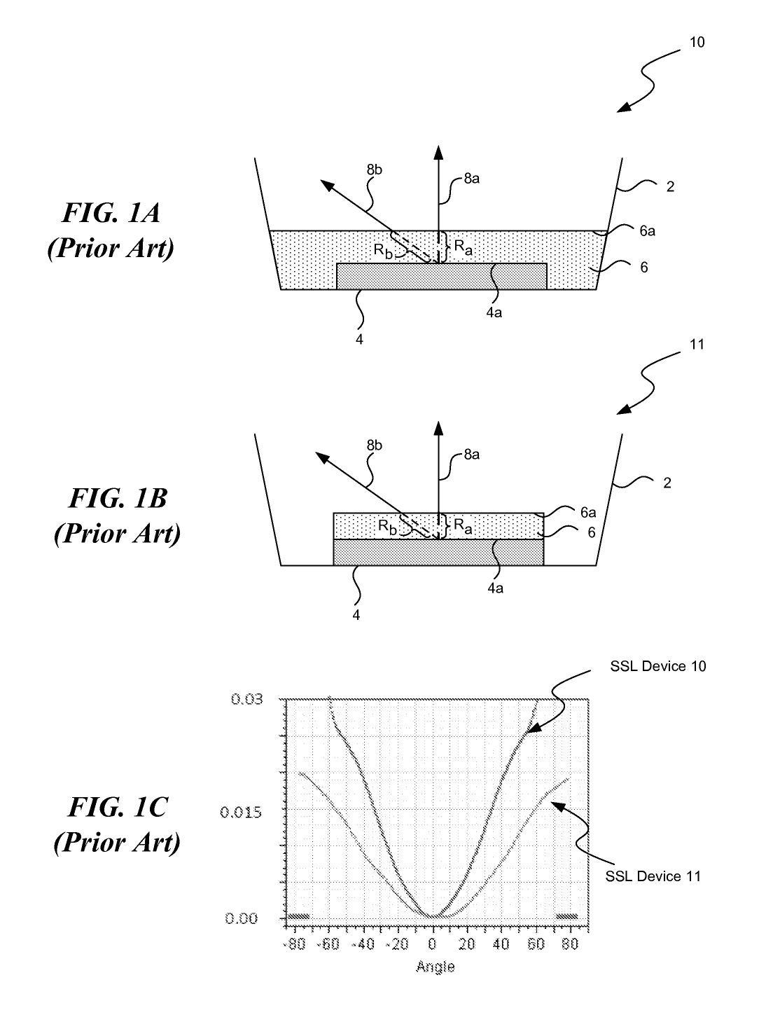

Several embodiments of the converter material 106 can also be configured to at least reduce angular color variations in the SSL device 100. It has been recognized that the morphology of converter materials can at least contribute to, if not cause, the angular color variations in SSL assemblies because the morphology can significantly impact the optical path lengths in the converter materials. For example, referring to FIGS. 1A and 1B, the first and second emissions 8a and 8b from the LED die 4 can have a first optical length Rₐ and a second optical length R_{b}, respectively. The first optical length Rₐ is shorter than the second optical length R_{b} based on a generally planar top surface 6a of the converter material 6. Without being bound by theory, it is believed that different optical path lengths Rₐ and R_{b} can cause the converter material 6 to have variations in conversion efficiencies. As a result, the first and second converted emissions corresponding to the first and second optical lengths Rₐ and R_{b} may have different center emission frequencies, intensities, and/or other emission characteristics. Accordingly, a combination of the emissions 8a and 8b from the LED die 4 and the converted emissions from the converter material 6 may appear to have different colors.

To at least lessen the impact of the foregoing angular conversion variations, in certain embodiments, the converter material 106 can have a morphology configured to at least reduce or minimize differences in optical path in the converter material 106 for emissions from the SSL die 104. In certain embodiments, the converter material 106 may have a converter surface 110 that is convex with a single curvature. For example, as shown in FIG. 2A, the converter surface 110 can be hemispherical or at least a portion of a sphere with an apex 111 generally corresponding to a central region 105a of the emission area 105. In operation, the SSL die 104 can produce a first emission 108a and a second emission 108b from the central region 105a. The first emission 108a is generally perpendicular to the first surface 104a of the SSL die, and the second emission 108b can be at an angle α of about 30°, 45°, or any angle other than 90° relative to the first emission 108a. Due to the contestant curvature of the converter surface 110, the first emission 108a can have a first optical path length R₁ that is at least approximate or equal to a second optical path length R₂ of the second emission 108b.

In other embodiments, the converter surface 110 of the converter material 106 can have different curvatures and/or other features that may be adjusted for different regions and/or emission angles of the emission area 105 based on a target color uniformity. For example, as shown in FIG. 2B, the converter material 106 can have a cross section that is a portion of an oval, a parabola, hyperbola, ellipse, and/or other suitable shapes with continually varying regional curvatures corresponding to regions of the emission area 105. As a result, the first optical path length R₁ of the first emission 108a in the converter material 106 can be generally equal to the second optical path length R₂ of the second emission 108b when the angle α is large (e.g., greater than about 75°). The first optical path length R₁ of the first emission 108a can also be larger than the second optical path length R₂ of the second emission 108b when the angle α is small (e.g., less than about 30°).

In other examples, the converter material 106 can have discretely varying regional curvatures. For example, as shown in FIG. 2C, the converter material 106 can include a first converter portion 106a, a second converter portion 106b, and a third converter portion 106c adjacent to one another. In the illustrated embodiment, the first and third converter portions 106a and 106c individually include a portion of a sphere. The second converter portion 106b includes a portion of an oval. In other embodiments, at least one of the first, second, and third converter portions 106a-106c can include a portion of a parabola, hyperbola, ellipse, and/or other suitable shapes.

In yet other examples, the converter surface 110 of the converter material 106 can include at least one portion with a generally planar surface. For example, as shown in FIG. 2D, the first and third converter portions 106a and 106c individually include a generally planar top surface 110a and 110c, respectively, while the second converter portion 106b has a convex cross section 110c. In other embodiments, the converter material 106 may include one, three, four, or any suitable number of portions with a generally planar surface.

Several embodiments of the converter material 106 may also be configured to increase a conversion efficiency of side emissions in the SSL die 104. For example, as shown in FIG. 2A, the SSL die 104 can also emit from the side surfaces 104c of the SSL die 104. The converter material 106 can at least increase a third optical path length R₃ of a side emission 108c such that the optical length difference between R₃ and R₁ (or R₂) is less than if the converter surface 110 is planar. As a result, a color variation between the side emission 108c and the first emission 108a (or second emission 108b) can be at least reduced. In other embodiments, the SSL die 104 may not produce side emissions.

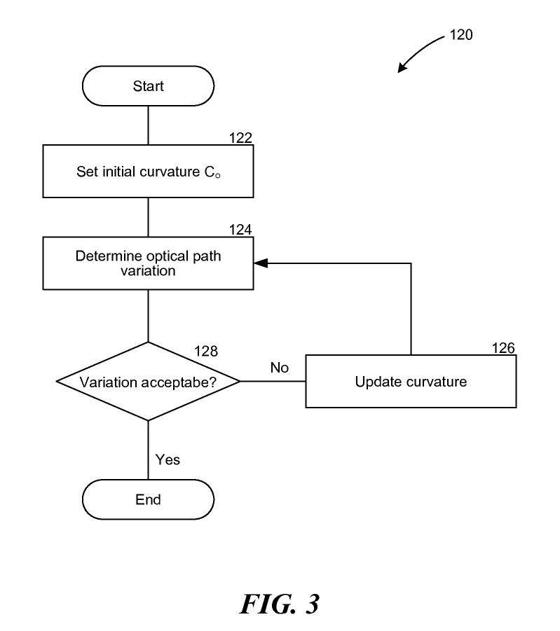

In certain embodiments, the curvature of the converter surface 110 of the converter material 106 may be empirically determined based on a target angular color variation. In other embodiments, the curvature of the converter surface 110 may be calculated based on a configuration of the emission area 105 of the SSL die 104. For example, FIG. 3 is a flow chart illustrating an iterative method 120 of generating curvature values for the converter material 106. The method 120 may be applied to the central region 105a of the emission area 105, or the method may be applied to other discrete regions of the emission area 105.

An initial stage of the method 120 includes setting initial curvature value Cₒ (block 122). In one embodiment, a single curvature value Cₒ may be set for the converter material 106. In another embodiment, a plurality of curvature values {Cₒ} may be set for a plurality of discrete regions of the converter material 106. The initial curvature value Cₒ may be set based on prior calculation results, based on a curvature of a sphere, and/or based on other suitable criteria.

Another stage of the method 120 can include determining optical path variation based on the initial curvature Cₒ and the geometry of the emission area 105 (block 124). In one embodiment, a plurality of optical path variations are calculated as a difference between a reference length and an optical path length at a particular angle for a particular region of the emission area 105. For example, as shown in FIG. 2A, the reference length can be the optical length for the first emission 108a, and the optical path variation for the second emission 108b from the central region 105a of the emission area 105 at the angle α can be calculated as:

ΔR₂=R₂−R₁

In general, optical path variations at other angles for the same central region 105a can be calculated as:

ΔRᵢ=Rᵢ−R₁

where i is an integer corresponding to an angle αᵢ. The optical path variations can then be summed up and/or otherwise combined to generate a representative optical path variation for the central region 105a. In other embodiments, the foregoing procedure for determining optical path variation may be repeated for other regions (e.g., a peripheral region) of the emission area 105.

Referring back to FIG. 3, another stage of the method 120 includes determining whether the representative optical path variation is acceptable (block 128). In one embodiment, the representative optical path variation is acceptable if it is below a predetermined threshold. In other embodiments, the representative optical path variation may be acceptable based on other suitable criteria.

If the representative optical path variation is acceptable, the process ends. If the representative optical path variation is not acceptable, another stage of the method 120 can include updating the curvature of the converter surface 110 from the initially set curvature Cₒ or a previous curvature (block 126). In one embodiment, updating the curvature can include incrementing or decrementing the curvature by a set value. In another embodiment, updating the curvature can include incrementing or decrementing the curvature by a variable value. In further embodiments, the curvature may be updated via other suitable mechanisms. The method 120 then reverts to determining optical path variation at block 124 based on the updated curvature value. The method 120 is then repeated until the representative path variation is deemed acceptable.

Even though an iterative process is discussed above with reference to FIG. 3, in further embodiments, the curvature values may be generated without iteration. For example, a path variation of the SSL device 100 may be represented as a function of the curvature of the converter surface 110 and the emission area 105 as follows:

ΔR=f(C,S)

where C and S are functions of the curvature and the geometry of the emission area 105, respectively. Values for the curvature function C can then be determined by minimizing the path variation function ΔR. In yet further embodiments, any of the foregoing and/or other suitable techniques may be combined to determine the curvature values for the converter surface 110 of the converter material 106.

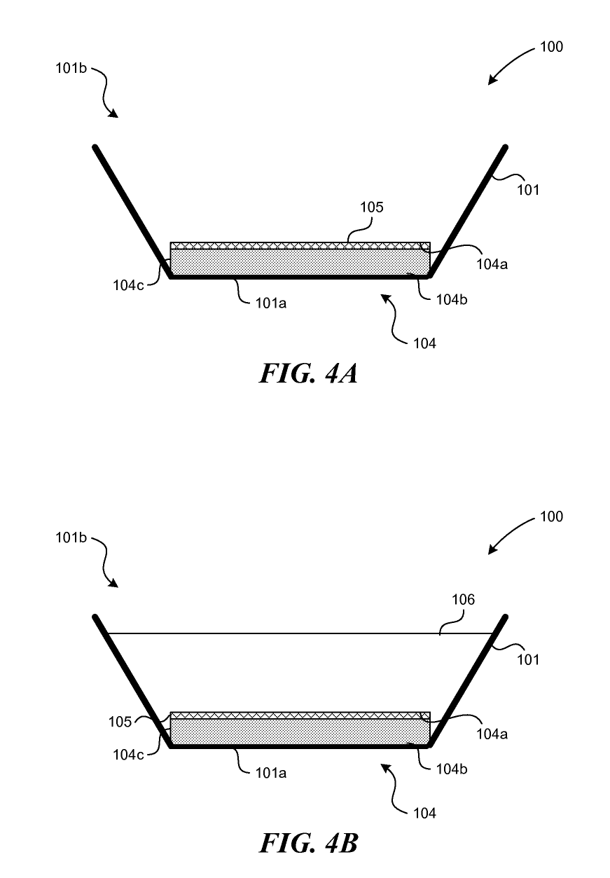

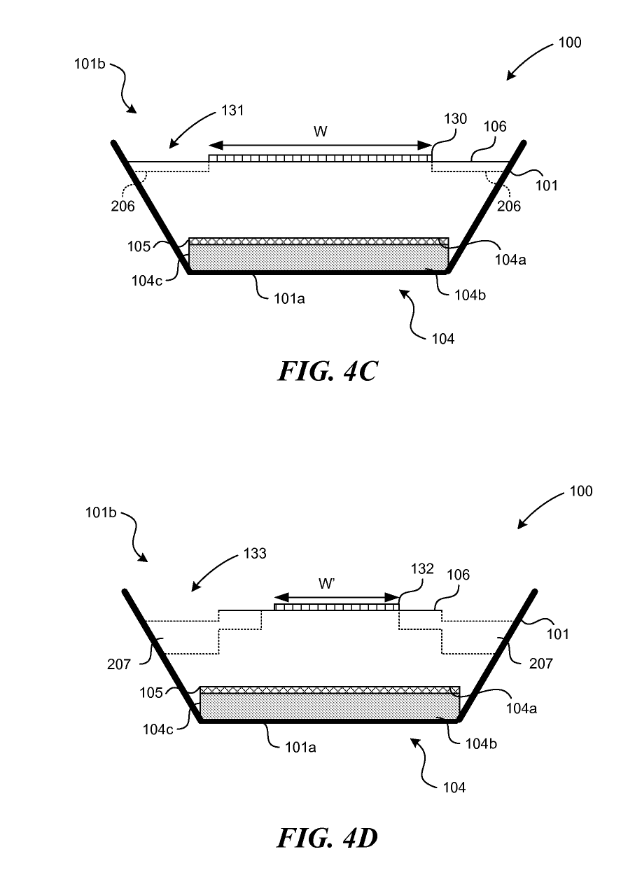

FIGS. 4A-4D are schematic cross-sectional diagrams of an SSL die undergoing a process to form the SSL device in FIGS. 2A-2D in accordance with embodiments of the technology. As shown in FIG. 4A, an initial stage of the process can include placing the SSL die 104 in the support structure 101. In one embodiment, the second surface 104b of the SSL die 104 is attached to the closed end 101a of the support structure 101 with an adhesive (not shown). In other embodiments, the SSL die 104 may be fastened to the support structure with a screw, a clip, and/or other suitable fasteners. In further embodiments, the SSL die 104 may simply rest on the closed end 101a of the support structure 101 without being fastened to the support structure 101.

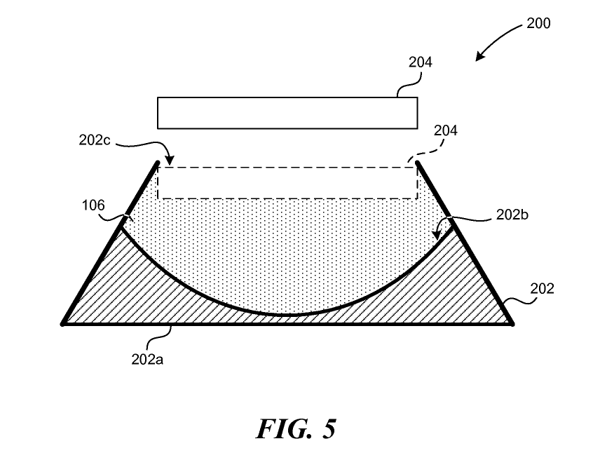

FIG. 4B shows another stage of the process in which the converter material 106 is disposed in the support structure 101. In one embodiment, the converter material 106 may be poured, injected, printed, and/or otherwise flowed into the support structure 101 and subsequently cured with heat, radio frequency energy, and/or other suitable mechanisms. In other embodiments, the converter material 106 may be pre-formed into a rigid form based on a shape of the support structure 101 and the SSL die 104 and placed into the support structure 101, as discussed in more detail below with reference to FIG. 5. In further embodiments, the converter material 106 may be disposed into the support structure 101 with other suitable techniques.

FIGS. 4C-4D show stages of the process in which the converter material 106 is patterned and partially removed to form a suitable curvature. As shown in FIG. 4C, a first masking material 130 (e.g., a photoresist) is deposited onto the converter material 106 and patterned with photolithography and/or other suitable techniques. The first masking material 130 includes openings 131 that expose a portion of the converter material 106. The process can then include removing a portion 206 (shown in dotted lines) of the converter material 106 through the openings 131 via wet etching, dry etching, laser ablation, and/or other suitable techniques.

As shown in FIG. 4D, the first masking material 130 can be removed from the converter material 106 and a second masking material 132 can be deposited onto the converter material 106. In the illustrated embodiment, the second masking material 132 has a width W′ that is less than the width W of the first masking material 130. In other embodiments, the second masking material 132 may have other geometric relations with the first masking material 130. The second masking material 132 can then be patterned to form openings 133 that expose additional portions of the converter material 106. The process can then include removing another portion 207 (shown in dotted lines) of the converter material 106 through the openings 133 via wet etching, dry etching, laser ablation, and/or other suitable techniques. The stages shown in FIGS. 4C and 4D can then be repeated to form a desired curvature profile for the converter material 106.

In other embodiments, the converter material 106 may be pre-formed into a suitable configuration using a stamp. FIG. 5 is a schematic cross-sectional diagram of a pre-form stamp 200 in accordance with embodiments of the technology. As shown in FIG. 5, the pre-form stamp 200 can include a base unit 202 and a press 204 that can moved relative to each other. The base unit 202 can include a bottom section 202a, an internal cavity 202b, and an opening 202c. The press 204 can include a plate, a slab, and/or other suitable structure that can move in/out of the opening 202c of the base unit 202.

The base unit 202 and the press 204 may have a shape, size, and/or other configurations that correspond to the desired configuration of the converter material 106. In the illustrated embodiment, the base unit 202 and the press 204 are shaped and sized to pre-form the converter material 106 as shown in FIG. 2A. In other embodiments, the base unit 202 and the press 204 can be shaped and sized to pre-form the converter material 106 as shown in FIGS. 2B-2D and/or of other suitable configurations.

In operation, the converter material 106 (e.g., a phosphor or a phosphor/silicone mixture) may be injected into the internal cavity 202b of the base unit 202. The press 204 (shown in phantom lines for clarity) can then be moved through the opening 202c into the internal cavity 202b of the base unit 202 to contact, compact, and/or otherwise exert a pressure on the injected converter material 106. The converter material 106 can then be cured by heat, radio frequency energy, and/or other suitable mechanisms to obtain the desired shape and/or other configurations.

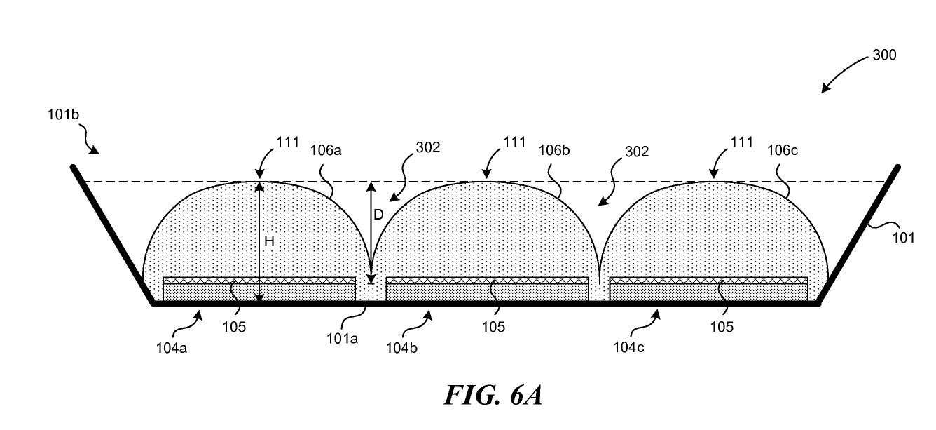

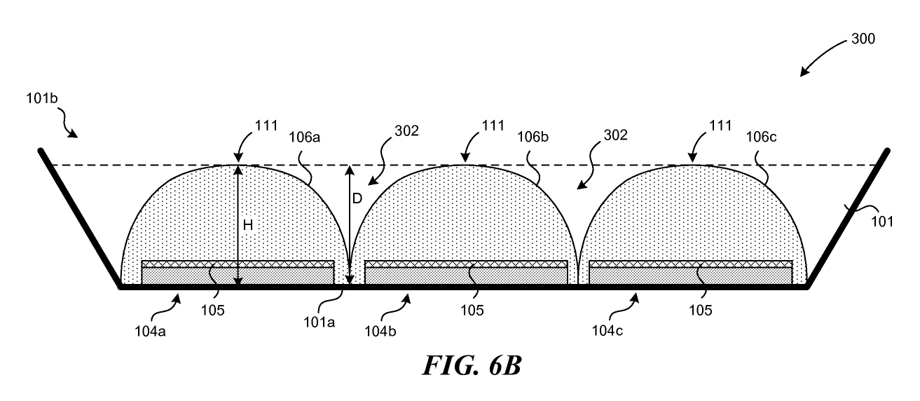

Even though the SSL device 100 discussed above with reference to FIGS. 2A-4D includes only one SSL die 104 in the support structure 101, in other embodiments, the SSL device 100 can also include a plurality of SSL dies 104. FIGS. 6A and 6B are schematic cross-sectional diagrams of an SSL device 300 with a plurality of SSL dies 104 in accordance with embodiments of the technology. As shown in FIG. 6A, the SSL device 300 includes a plurality of SSL dies 104 (identified individually as first, second, and third SSL dies 104a, 104b, and 104c, respectively) and a plurality of corresponding converter materials 106 (identified individually as first, second, and third converter materials 106a, 106b, and 106c, respectively). The adjacent converter materials 106 are separated from each other by a gap 302.

The individual SSL dies 104 and the converter materials 106 can be configured to at least reduce angular color variations in the SSL device 300, as discussed in more detail above with reference to FIGS. 2A-2D. In the illustrated embodiment, the first, second, and third SSL dies 104 and the first, second, and third converter materials 106 have generally similar configurations. In other embodiments, the first, second, and third SSL dies 104 and the first, second, and third converter materials 106 can have different shapes, sizes, and/or other configurations.

The gaps 302 can extend toward the SSL dies 104 to a suitable depth based on configurations of the SSL dies 104. For example, as shown in FIG. 6A, the gaps 302 extend from apexes 111 of the converter materials 106 to a depth D that is less than a height H of the apexes 111 relative to the closed end 101a of the support structure 101. FIG. 6B shows another embodiment in which the depth D of the gaps 302 generally equals the height H of the apexes 111. In further embodiments, the depth D of the gaps 302 can have other suitable relationships to the height H of the apexes 111.

From the foregoing, it will be appreciated that specific embodiments of the technology have been described herein for purposes of illustration, but that various modifications may be made without deviating from the disclosure. In addition, many of the elements of one embodiment may be combined with other embodiments in addition to or in lieu of the elements of the other embodiments. Accordingly, the disclosure is not limited except as by the appended claims.

I/We claim:

1. A solid state lighting (SSL) device, comprising:
a support structure;
an SSL die in the support structure; and
a converter material at least partially encapsulating the SSL die, the converter material having a surface facing away from the SSL die, wherein the surface of the converter material has a shape configured with respect to at least one of a shape and a size of the SSL die such that an angular difference in optical path length in the converter material is below a predetermined threshold.

2. The SSL device of claim 1 wherein:
the support structure has a trapezoidal cross section with a closed end and an open end opposite the closed end;
the SSL die includes an N-type gallium nitride (GaN) material, an indium gallium nitride (InGaN) material, and a P-type GaN material on one another in series;
the SSL die is a first SSL die;
the SSL device further includes a second SSL die adjacent the first SSL die;
the converter material includes at least one of cerium(III)-doped yttrium aluminum garnet (“YAG”), neodymium-doped YAG, neodymium-chromium double-doped YAG, erbium-doped YAG, ytterbium-doped YAG, neodymium-cerium double-doped YAG, holmium-chromium-thulium triple-doped YAG, thulium-doped YAG, chromium(IV)-doped YAG, dysprosium-doped YAG, samarium-doped YAG, terbium-doped YAG, CaS:Eu, CaAlSiN₃:Eu, Sr₂Si₅N₈:Eu, SrS:Eu, Ba₂Si₅N₈:Eu, Sr₂SiO₄:Eu, SrSi₂N₂O₂:Eu, SrGa₂S₄:Eu, SrAl₂O₄:Eu, Ba₂SiO₄:Eu, Sr₄Al1₄O₂₅:Eu, SrSiAl₂O₃N:Eu, BaMgAl₁₀O₁₇:Eu, Sr₂P₂O₇:Eu, BaSO₄:Eu, and SrB₄O₇:Eu;
the converter material includes a first portion generally corresponding to the first SSL die and a second portion generally corresponding to the second SSL die;
the first and second portions of the converter material are separated from each other by a gap;
the surfaces of the first and second portions of the converter individually have a convex shape with an apex and with a single curvature; and
the gap has a depth that is less than a height of the apex of the first or second portion of the converter material.

3. The SSL device of claim 1 wherein:
the support structure has a trapezoidal cross section with a closed end and an open end opposite the closed end;
the SSL die includes an N-type gallium nitride (GaN) material, an indium gallium nitride (InGaN) material, and a P-type GaN material on one another in series;
the SSL die is a first SSL die;
the SSL device further includes a second SSL die adjacent the first SSL die;
the converter material includes at least one of cerium(III)-doped yttrium aluminum garnet (“YAG”), neodymium-doped YAG, neodymium-chromium double-doped YAG, erbium-doped YAG, ytterbium-doped YAG, neodymium-cerium double-doped YAG, holmium-chromium-thulium triple-doped YAG, thulium-doped YAG, chromium(IV)-doped YAG, dysprosium-doped YAG, samarium-doped YAG, terbium-doped YAG, CaS:Eu, CaAlSiN₃:Eu, Sr₂Si₅N₈:Eu, SrS:Eu, Ba₂Si₅N₈:Eu, Sr₂SiO₄:Eu, SrSi₂N₂O₂:Eu, SrGa₂S₄:Eu, SrAl₂O₄:Eu, Ba₂SiO₄:Eu, Sr₄Al1₄O₂₅:Eu, SrSiAl₂O₃N:Eu, BaMgAl₁₀O₁₇:Eu, Sr₂P₂O₇:Eu, BaSO₄:Eu, and SrB₄O₇:Eu;
the converter material includes a first portion generally corresponding to the first SSL die and a second portion generally corresponding to the second SSL die;
the first and second portions of the converter material are separated from each other by a gap;
the surfaces of the first and second portions of the converter individually have a convex shape with an apex and with a single curvature; and
the gap has a depth that is generally equal to a height of the apex of the first or second portion of the converter material.

4. The SSL device of claim 1 wherein:
the SSL die is a first SSL die;
the SSL device further includes a second SSL die adjacent the first SSL die;
the converter material includes a first portion generally corresponding to the first SSL die and a second portion generally corresponding to the second SSL die;
the first and second portions of the converter material are separated from each other by a gap;
the surfaces of the first and second portions of the converter individually have a convex shape with an apex and with a single curvature; and
the gap has a depth that is less than a height of the apex of the first or second portion of the converter material.

5. The SSL device of claim 1 wherein:
the SSL die is a first SSL die;
the SSL device further includes a second SSL die adjacent the first SSL die;
the converter material includes a first portion generally corresponding to the first SSL die and a second portion generally corresponding to the second SSL die;
the first and second portions of the converter material are separated from each other by a gap;
the surfaces of the first and second portions of the converter individually have a convex shape with an apex and with a single curvature; and
the gap has a depth that is generally equal to a height of the apex of the first or second portion of the converter material.

6. The SSL device of claim 1 wherein:
the SSL die is a first SSL die;
the SSL device further includes a second SSL die adjacent the first SSL die;
the second SSL die is generally similar in structure and function to the first SSL die;
the converter material includes a first portion generally corresponding to the first SSL die and a second portion generally corresponding to the second SSL die; and
the first portion and the second portion of the converter material are generally similar in shape.

7. The SSL device of claim 1 wherein:
the SSL die is a first SSL die;
the SSL device further includes a second SSL die adjacent the first SSL die;
the second SSL die is generally similar in structure and function to the first SSL die;
the converter material includes a first portion generally corresponding to the first SSL die and a second portion generally corresponding to the second SSL die;
the first portion of the converter material has a first shape; and
the second portion of the converter material has a second shape different than the first shape.

8. The SSL device of claim 1 wherein:
the SSL die is a first SSL die having a first die dimension;
the SSL device further includes a second SSL die adjacent the first SSL die;
the second SSL die has a second die dimension different than the first die dimension;
the converter material includes a first portion generally corresponding to the first SSL die and a second portion generally corresponding to the second SSL die;
the first portion of the converter material has a first shape and a first dimension;
the second portion of the converter material has a second shape and a second dimension; and
at least one of the first shape and first dimension is different than the corresponding second shape and second dimension.

9. A solid state lighting (SSL) device, comprising:
a support structure;
an SSL die in the support structure; and
a converter material at least partially encapsulating the SSL die, the converter material being configured to emit under photoluminescence, the converter material having a surface facing away from the SSL die, wherein the surface of the converter material has a generally convex shape.

10. The SSL device of claim 9 wherein the surface of the converter material has a single curvature.

11. The SSL device of claim 9 wherein the surface of the converter material has a shape that is a portion of a circle.

12. The SSL device of claim 9 wherein the surface of the converter material has a continuously varying curvature.

13. The SSL device of claim 9 wherein the surface of the converter material has a planar portion.

14. The SSL device of claim 9 wherein:
the surface of the converter material includes a first portion and a second portion;
the first portion has a single curvature or continuously varying curvatures; and
the second portion is generally planar.

15. The SSL device of claim 9 wherein:
the SSL die includes a first surface, a second surface opposite the first surface, and a side surface between the first and second surfaces;
the converter material has a first optical length relative to the first surface of the SSL die;
the converter material has a second optical length relative to the side surface of the SSL die; and
the first optical length is generally equal to the second optical length.

16. The SSL device of claim 9 wherein:
the SSL die includes a first surface facing the converter material and a second surface opposite the first surface;
the converter material has a first optical length relative to the first surface of the SSL die at a first angle;
the converter material has a second optical length relative to the first surface of the SSL die at a second angle different than the first angle; and
the first optical length is generally equal to the second optical length.

17. The SSL device of claim 9 wherein:
the SSL die includes a first surface facing the converter material and a second surface opposite the first surface;
the converter material has a first optical length relative to the first surface of the SSL die at a first angle of about 90° relative to the first surface of the SSL die;
the converter material has a second optical length relative to the first surface of the SSL die at a second angle of about 30° relative to the first surface of the SSL die; and
the first optical length is generally equal to the second optical length.

18. A method for forming a solid state lighting (SSL) assembly, comprising:
placing an SSL die in a support structure;
at least partially encapsulating the SSL die with a converter material, the converter material being configured to emit under photoluminescence; and
forming a surface of the converter material based on at least one of a shape and size of the SSL die such that an angular difference in optical path length in the converter material is below a predetermined threshold.

19. The method of claim 18 wherein forming the surface of the converter material includes:
placing the converter material in the support structure, the converter material having a generally planar surface;
patterning the converter material based on at least one of a shape and size of the SSL die such that the angular difference in optical path length in the converter material is below a predetermined threshold; and
removing material from the generally planar surface of the converter material, thereby forming a generally convex surface of the converter material.

20. The method of claim 18 wherein forming the surface of the converter material includes pre-forming the converter material having the surface with a stamp.

21. The method of claim 18 wherein:
forming the surface of the converter material includes pre-forming the converter material having the surface with a stamp; and
at least partially encapsulating the SSL die includes placing the pre-formed converter material onto the SSL die.

22. The method of claim 18 wherein forming a surface of the converter material includes:
calculating a first optical path length in the converter material at a first angle relative to a region of the SSL die;
calculating a second optical path length in the converter material at a second angle relative to the region of the SSL die, the second angle being different than the first angle;
obtaining a difference between the first and second optical paths; and
determining whether the difference is below a target threshold.

23. The method of claim 18 wherein forming a surface of the converter material includes:
calculating a first optical path length in the converter material at a first angle relative to a region of the SSL die;
calculating a second optical path length in the converter material at a second angle relative to the region of the SSL die, the second angle being different than the first angle;
obtaining a difference between the first and second optical paths;
determining whether the difference is below a target threshold; and
if the difference is above the target threshold, adjusting a characteristic of the surface and repeating the calculating, obtaining, and determining operations.
